(19) United States
(12) Patent Application Publication
(10) Pub. No.: US 2022/0205135 A1
(43) Pub. Date: Jun. 30, 2022

(54) METHOD FOR PRODUCING PRODUCT HAVING OXIDE FILM

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP); National University Corporation Kyoto Institute of Technology, Kyoto-shi (JP)

(72) Inventors: TATSUJI NAGAOKA, Nisshin-shi (JP); HIROYUKI NISHINAKA, Kyoto-shi (JP); MASAHIRO YOSHIMOTO, Kyoto-shi (JP)

(21) Appl. No.: 17/537,697

(22) Filed: Nov. 30, 2021

(30) Foreign Application Priority Data
Dec. 25, 2020 (JP) 2020-217566

(51) Int. Cl. C30B 25/14; C01G 15/00; C30B 29/16

(52) U.S. Cl. CPC C30B 25/14; C01G 15/00; C01P 2006/40; C01P 2002/54; C30B 29/16

(57) ABSTRACT

A method for producing a product including an oxide film of a second metal that is doped with a first metal includes generating a mist from a raw material solution in which both the first metal and the second metal are dissolved, and supplying the mist to a surface of a substrate to form the oxide film on the surface of the substrate. A pH of the raw material solution is less than 7.

### CROSS REFERENCE TO RELATED APPLICATION

This application is based on Japanese Patent Application No. 2020-217566 filed on Dec. 25, 2020, the disclosure of which is incorporated herein by reference in its entirety.

### TECHNICAL FIELD

The techniques disclosed herein relate to a method for producing a product having an oxide film.

### SUMMARY

A method for producing a product having an oxide film of a second metal that is doped with a first metal is provided. This production method includes generating a mist from a raw material solution in which both the first metal and the second metal are dissolved, and supplying the mist to a surface of a substrate to form the oxide film on the surface of the substrate. A pH of the raw material solution is less than 7. This production method may include generating a first mist from a first raw material solution in which the first metal is dissolved, generating a second mist from a second raw material solution in which the second metal is dissolved, and supplying the first mist and the second mist to a surface of a substrate to form the oxide film on the surface of the substrate. A pH of the first raw material solution is less than 7.

### BRIEF DESCRIPTION OF DRAWINGS

FIG. 1 is a diagram schematically illustrating a film forming apparatus 10 used in a production method of the first embodiment.

FIG. 2 is a cross-sectional view schematically illustrating a product 2 produced by the production method of the first embodiment.

FIG. 3 is a flowchart illustrating steps included in the production method of the first embodiment.

FIG. 4 is a diagram illustrating a step (S12) of preparing a raw material solution 23 of the first embodiment.

FIG. 5 is a flowchart illustrating steps of a production method of the second embodiment.

FIG. 6 is a diagram illustrating a step (S12A) of preparing the raw material solution 23 of the second embodiment.

FIG. 7 is a diagram illustrating a step (S12B) of preparing the raw material solution 23 of the second embodiment.

FIG. 8 is a flowchart illustrating steps of a production method of the third embodiment.

FIG. 9 is a diagram illustrating a step (S12C) of preparing the raw material solution 23 of the third embodiment.

FIG. 10 is a diagram schematically illustrating a film forming apparatus 100 used in a production method of the fourth embodiment.

FIG. 11 is a table of standard reduction oxidation potentials in aqueous solutions of metals and hydrogen exemplified in this disclosure.

FIG. 12 is a table of standard reduction oxidation potentials in aqueous solutions of metals and hydrogen exemplified in this disclosure.

### DESCRIPTION OF EMBODIMENTS

To begin with, examples of relevant techniques will be described.

The techniques disclosed herein relate to a method for producing a product having an oxide film. The product in the present specification includes not only a final product having a certain use and function, but also a semi-finished product temporarily manufactured in the manufacturing process of the final product.

For example, a method for producing a semiconductor device includes a step of preparing one or more raw material solutions, a step of generating mist from each of the one or more raw material solutions, and a step of supplying the mist to a surface of a substrate. A metal as a dopant is dissolved in the raw material solution and the mist of the raw material solution is supplied to the surface of the substrate, so that a metal-doped oxide film is deposited on the surface of the substrate. This type of technique is sometimes referred to as a mist chemical vapor deposition (CVD).

The above-mentioned production method has a problem that the characteristics of the generated oxide film are different from the intended characteristics. The present disclosure provides a technique that suppresses variations in characteristics of an oxide film caused by the production method and that makes it possible to produce the oxide film with high quality.

One of the factors that cause the characteristics of the generated oxide film to differ from the intended characteristics is that the concentration of the dopant contained in the oxide film differs from the intended concentration. In this regard, it was found that, in the raw material solution in which the metal serving as the dopant was dissolved, the metal reacted with hydroxide ion and precipitated as a hydroxide. The formation of such hydroxides unintentionally reduces the concentration of the metal dissolved in the raw material solution. Then, when the concentration of the metal dissolved in the raw material solution decreases, the concentration of the dopant contained in the oxide film also decreases. As a result, the concentration of the dopant contained in the oxide film is different from the intended concentration, which causes the above-mentioned problem that the intended characteristics of the oxide film cannot be obtained.

Based on this findings, in the techniques disclosed herein, the pH of the raw material solution in which the metal as the dopant is dissolved is less than 7. When the pH of the raw material solution is less than 7, the concentration of hydroxide ions in the raw material solution decreases. By lowering the concentration of hydroxide ions, it is possible to restrict the metal serving as a dopant from precipitating as a hydroxide. This makes it possible to correctly adjust the concentration of the metal dissolved in the raw material solution and maintain the concentration at the intended value.

Based on the above technique, a method for producing a product having an oxide film of a second metal that is doped with a first metal is provided. This production method includes generating a mist from a raw material solution in which both the first metal and the second metal are dissolved, and supplying the mist to a surface of a substrate to form the oxide film on the surface of the substrate. A pH of the raw material solution is less than 7. This production method may include generating a first mist from a first raw material solution in which the first metal is dissolved, generating a second mist from a second raw material solution in which the second metal is dissolved, and supplying the first mist and the second mist to a surface of a substrate to form the oxide film on the surface of the substrate. A pH of the first raw material solution is less than 7.

According to the above-mentioned production method, it is possible to prevent the first metal from precipitating as a hydroxide in the raw material solution in which the first metal serving as a dopant is dissolved. Thereby, the concentration of the first metal dissolved in the raw material solution can be correctly adjusted and maintained at the intended concentration. As a result, the concentration of the first metal contained in the oxide film is stabilized and manufacturing variations in the characteristics of the oxide film can be suppressed.

In one embodiment of the present techniques, in a raw material solution (25° C.) in which a first metal is dissolved, the standard oxidation reduction potential of the first metal may be less than that of hydrogen. According to such a configuration, it is possible to further restrict the first metal from precipitating as a hydroxide in the raw material solution in which the first metal is dissolved.

In one embodiment of the present disclosure, the first metal may be at least one of Li, K, Rb, Cs, Ba, Ra, Sr, Ca, Na, Mg, No, Md, La, Fm, Y, Ce, Nd, Lu, Sm, Gd, Yb, Es, Ac, Cf, Am, Cm, Sc, Bk, Pu, Eu, Be, Th, Np, Hf, Al, U, Ti, Zr, Mn, V, Nb, Cr, Zn, Ga, Fe, Cd, In, Tl, Co, Ni, Mo, Sn and Pb. These metals are examples of metals whose standard oxidation reduction potential in the raw material solution is less than that of hydrogen.

In one embodiment of the present disclosure, the concentration of the first metal in the raw material solution in which the first metal is dissolved may be 1 mol/L or less. However, the concentration of the first metal in the raw material solution is not limited to this numerical range, and can be appropriately set according to the desired characteristics of the oxide film.

In one embodiment of the present disclosure, the method may further include dissolving the first metal in an acidic solution and adjusting a pH of the acidic solution to be less than 7. According to this configuration, the concentration of the first metal to be dissolved in the raw material solution can be correctly adjusted and maintained at the intended concentration. For example, by adjusting the pH of the acidic solution to a relatively low value in the step of dissolving the first metal in the acidic solution, the first metal can be promoted to be dissolved. After that, the pH of the acidic solution in which the first metal is dissolved may be increased to a value that is less than 7.

In the above-described embodiment, in the step of dissolving the first metal in the acidic solution, the first metal may be dissolved in the acidic solution in a container made of a material free from silicon (Si). According to this configuration, it is possible to prevent Si, which is an impurity, from being mixed into the raw material solution from the container in the step of preparing the raw material solution. In contrast, if the container is made of a material containing Si, Si may unintentionally contaminate the raw material solution. When Si contaminates the raw material solution, the generated oxide film may also contain Si. Even if the amount of Si contained in the oxide film is very small, it may significantly affect the characteristics of the oxide film.

In the above-described embodiment, in the step of dissolving the first metal in the acidic solution, the container may be maintained at a positive pressure relative to the atmosphere with a gas generated when the first metal is being dissolved in the acidic solution. According to this configuration, it is possible to prevent impurities in the air from being unintentionally mixed into the raw material solution.

In one embodiment of the present disclosure, a production method includes generating a first mist from a first raw material solution in which the first metal is dissolved and generating a second mist from a second raw material solution in which the second metal is dissolved. A pH of the second raw material solution in which the second metal is dissolved may be less than 7. According to this configuration, even in the second raw material solution in which the second metal is dissolved, it is possible to restrict the second metal from precipitating as a hydroxide. The concentration of the second metal dissolved in the second raw material solution can be correctly adjusted and maintained at the intended concentration, so that the oxide film can be generated with high quality.

In one embodiment of the present disclosure, the standard oxidation reduction potential of the second metal may be less than that of hydrogen in the raw material solution in which the second metal is dissolved. According to this configuration, it is possible to further restrict the second metal from precipitating as a hydroxide in the raw material solution in which the second metal is dissolved.

In one embodiment of the present disclosure, the second metal may be at least one of Li, K, Rb, Cs, Ba, Ra, Sr, Ca, Na, Mg, No, Md, La, Fm, Y, Ce, Nd, Lu, Sm, Gd, Yb, Es, Ac, Cf, Am, Cm, Sc, Bk, Pu, Eu, Be, Th, Np, Hf, Al, U, Ti, Zr, Mn, V, Nb, Cr, Zn, Ga, Fe, Cd, In, Tl, Co, Ni, Mo, Sn and Pb. These metals are examples of metals whose standard oxidation reduction potential in the raw material solution is less than that of hydrogen. The second metal is different from the first metal.

In one embodiment of the present disclosure, the concentration of the second metal in the raw material solution in which the second metal is dissolved may be 1 mol/L or less. However, the concentration of the second metal in the raw material solution is not limited to this numerical range, and can be appropriately set according to the desired characteristics of the oxide film.

In one embodiment of the present disclosure, the method may further include dissolving the second metal in an acidic solution and adjusting a pH of the acidic solution in which the second metal is dissolved to be less than 7. According to this configuration, the concentration of the second metal to be dissolved in the raw material solution can be correctly adjusted and maintained at the intended concentration.

In the above-described embodiment, in the step of dissolving the second metal in the acidic solution, the second metal may be dissolved in the acidic solution in a container made of a material free from Si. According to this configuration, it is possible to prevent Si, which is an impurity, from being mixed into the raw material solution from the container in the step of preparing the raw material solution.

In the above-described embodiment, in the step of dissolving the second metal in the acidic solution, the container may be maintained at a positive pressure relative to the atmosphere with a gas generated when the second metal is being dissolved in the acidic solution. According to this configuration, it is possible to prevent impurities in the air from being unintentionally mixed into the raw material solution.

In one embodiment of the present disclosure, the oxide film may be a single crystal film. In addition, or instead, the oxide film may be a semiconductor film.

### First Embodiment

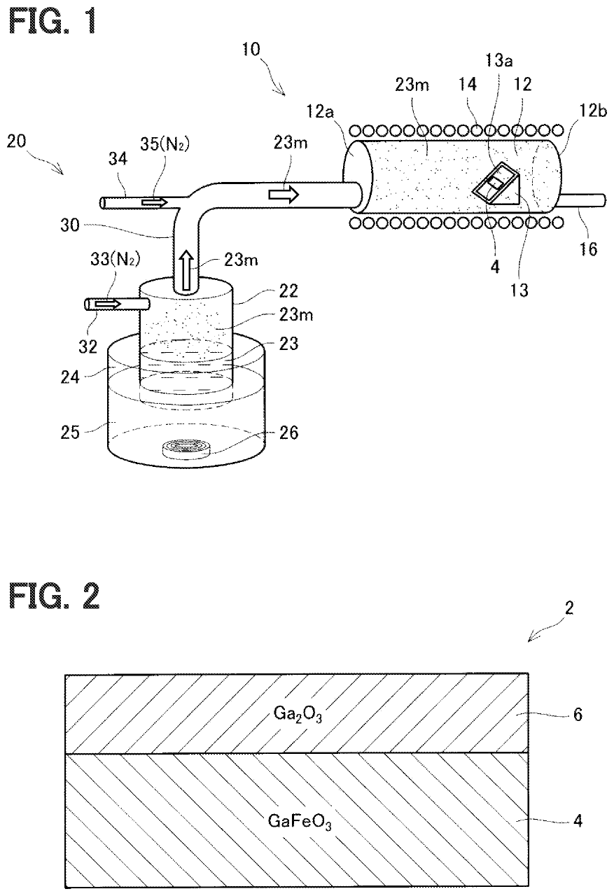

With reference to the drawings, a production method of the first embodiment will be described. The production method of this embodiment is mainly carried out by a film forming apparatus 10 shown in FIG. 1, and a product 2 shown in FIG. 2 is produced. As shown in FIG. 2, the product 2 has an oxide film 6 on a surface of a substrate 4. The oxide film 6 is composed of an oxide of a second metal that is doped with a first metal. The product 2 here is not limited to a final product having a certain use and function, but also includes a semi-finished product temporarily produced in the process of producing the final product.

The product 2 is, for example, a semiconductor device or a semi-finished product of the semiconductor device. As an example, the first metal may be magnesium (Mg) and the second metal may be gallium (Ga). In this case, the oxide film 6 is a film of gallium oxide (Ga₂O₃) containing magnesium as a dopant. The substrate 4 may be made of gallium iron oxide (GaFeO₃). The coating film of gallium oxide (Ga₂O₃) containing magnesium is a single crystal film and a semiconductor film. However, the oxide film 6 in this embodiment is not limited to this. The oxide film 6 is not limited to a single crystal film, and may be a polycrystalline film. Further, the oxide film 6 is not limited to the semiconductor film, and may be an insulating film or a conductor film.

First, the film forming apparatus 10 will be described with reference to FIG. 1. The film forming apparatus 10 is configured to form the oxide film 6 on the surface of the substrate 4 by using the mist CVD method. The substrate 4 is not limited to the gallium iron oxide substrate described above, and may be another semiconductor substrate or other substrate. The film forming apparatus 10 includes a chamber 12 in which the substrate 4 is arranged, a heater 14 for heating the chamber 12, and a mist generating device 20 connected to the chamber 12.

The specific configuration of the chamber 12 is not particularly limited. As an example, the chamber 12 in this embodiment has an upstream end 12a and a downstream end 12b, and extends tubularly from the upstream end 12a to the downstream end 12b in the longitudinal direction. The mist generating device 20 is connected to the upstream end 12a of the chamber 12. An exhaust pipe 16 is connected to the downstream end 12b of the chamber 12.

A stage 13 for supporting the substrate 4 is disposed in the chamber 12. The stage 13 has a tilted surface 13a on which the substrate 4 is arranged. The tilted surface 13a is tilted with respect to the longitudinal direction of the chamber 12. Although not particularly limited, the angle formed by the tilted surface 13a with respect to the longitudinal direction of the chamber 12 may be, for example, within the range of 30 degrees to 60 degrees, and may be, for example, 45 degrees.

The specific configuration of the heater 14 is also not particularly limited. As an example, the heater 14 in this embodiment has multiple ring heaters. The multiple ring heaters are arranged in the longitudinal direction of the chamber 12. Each of the ring heaters has a ring shape and the ring heaters are arranged along the outer circumferential surface of the chamber 12 to surround the chamber 12. The ring heaters are divided into groups along the longitudinal direction of the chamber 12, and operations of the ring heaters are controlled for the groups.

The mist generating device 20 includes a raw material solution tank 22, a water tank 24, and an ultrasonic vibrator 26. The raw material solution tank 22 is a container for storing the raw material solution 23. As will be described in detail later, a first metal and a second metal, which are main raw materials of the oxide film 6, are dissolved in the raw material solution 23. The raw material solution tank 22 is connected to the upstream end 12a of the chamber 12 through a mist supply passage 30. The water tank 24 is a container for storing water 25. The upper part of the water tank 24 is open, and the raw material solution tank 22 is inserted into the water tank 24 from the open upper part. The bottom surface of the raw material solution tank 22 is immersed in the water 25 in the water tank 24.

The ultrasonic vibrator 26 is a device that generates ultrasonic waves. The ultrasonic vibrator 26 is arranged on the bottom of the water tank 24 and faces the bottom surface of the raw material solution tank 22. The ultrasonic waves generated by the ultrasonic vibrator 26 is transmitted to the raw material solution 23 in the raw material solution tank 22 through the water 25 in the water tank 24. When the ultrasonic waves are transmitted to the raw material solution 23, the surface of the raw material solution 23 vibrates, so that mist 23m of the raw material solution 23 is generated in the raw material solution tank 22. Here, the bottom surface of the raw material solution tank 22 is preferably a film made of a flexible material, whereby ultrasonic waves are easily transmitted to the raw material solution 23.

The mist 23m generated in the raw material solution tank 22 is supplied into the chamber 12 through the mist supply passage 30. A carrier gas supply passage 32 is fluidly connected to the raw material solution tank 22, and a dilution gas supply passage 34 is fluidly connected to the mist supply passage 30. The carrier gas supply passage 32 supplies a carrier gas 33 such as N₂ (nitrogen) into the raw material solution tank 22. The dilution gas supply passage 34 supplies a dilution gas 35 such as N₂ (nitrogen) into the mist supply passage 30. The mist 23m is conveyed into the chamber 12 at an appropriate density by the carrier gas 33 and the dilution gas 35.

In the chamber 12, a gas containing the mist 23m flows from the upstream end 12a to the downstream end 12b. The substrate 4 is arranged in the chamber 12, and the mist 23m of the raw material solution 23 is supplied to the surface of the substrate 4. As described above, the first metal and the second metal are dissolved in the raw material solution 23, and the mist 23m contains ions of the first metal and the second metal. As a result, the oxide of the second metal is deposited on the surface of the substrate 4 while incorporating the first metal as a dopant into the substrate 4. That is, the oxide film 6 of the second metal doped with the first metal is formed on the surface of the substrate 4.

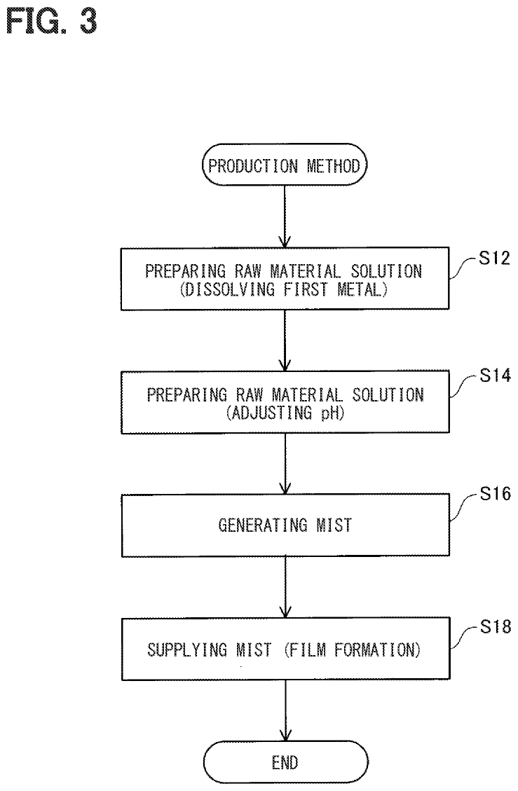

Next, a production method of the present embodiment using the film forming apparatus 10 will be described with reference to FIG. 3. As shown in FIG. 3, the production method of this embodiment mainly includes a step of preparing the raw material solution 23 (S12, S14), a step of generating mist 23m from the raw material solution 23 (S16), and a step of supplying the mist 23m to the surface of the substrate 4 (S18). As is clear from the above description, the step of generating the mist 23m from the raw material solution 23 (S16) is carried out by the mist generating device 20, and the step of supplying the mist 23m to the surface of the substrate 4 (S18) is carried out in the chamber 12. These steps (S16, S18) are carried out in parallel at the same time, and the oxide film 6 is formed on the surface of the substrate 4. As described above, the first metal and the second metal are dissolved in the raw material solution 23. By appropriately adjusting the concentration of the first metal and the concentration of the second metal in the raw material solution 23, the oxide film 6 of the second metal doped with the first metal can be formed.

In contrast, the step of preparing the raw material solution 23 (S12, S14) are carried out prior to the film formation by the film forming apparatus 10. As will be described in detail later, in this step, an acidic raw material solution 23 having a pH adjusted to be less than 7 is prepared. The pH of the raw material solution 23 is maintained at a value less than 7 even in the step of generating the mist 23m (S16). As a result, it is possible to prevent the first metal dissolved in the raw material solution 23 from precipitating as a hydroxide, and the concentration of the first metal is correctly adjusted and maintained at the intended concentration. As a result, the concentration of the first metal contained in the oxide film 6 is stabilized and it is possible to suppress manufacturing variations in the characteristics of the oxide film 6. The lower the pH of the raw material solution 23 is, the more strongly it is possible to prevent the first metal from precipitating as a hydroxide. From this point of view, the pH of the raw material solution 23 may be less than 5 or less than 3.

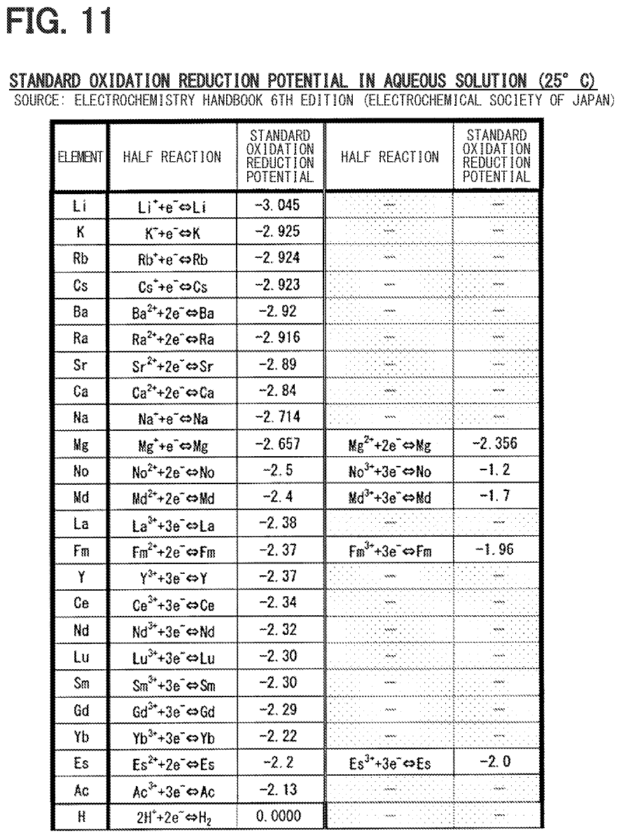

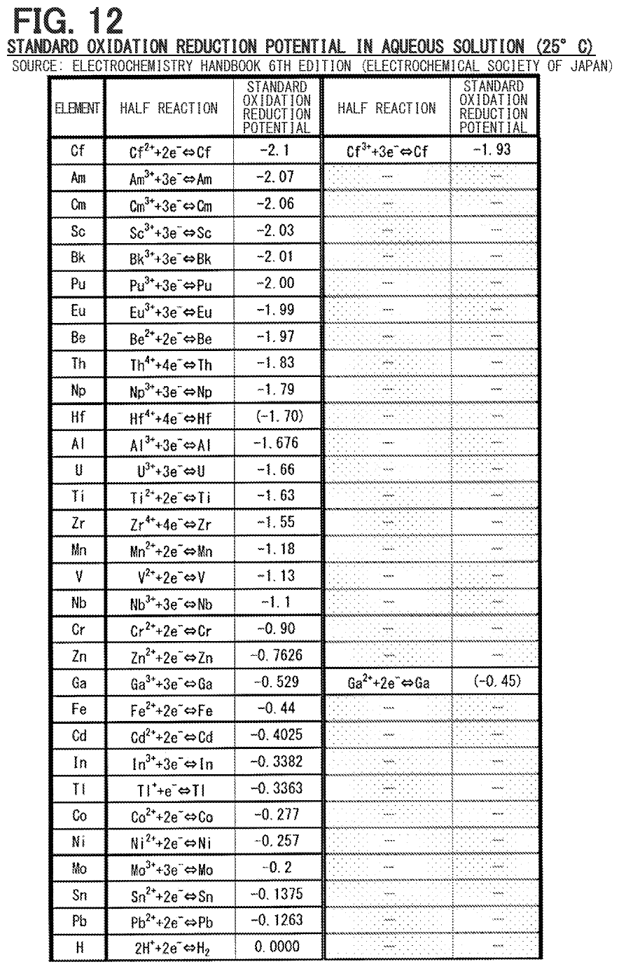

The first metal is not limited to the magnesium exemplified above. The first metal may be selected from the group consisting of Li, K, Rb, Cs, Ba, Ra, Sr, Ca, Na, Mg, No, Md, La, Fm, Y, Ce, Nd, Lu, Sm, Gd, Yb, Es, Ac, Cf, Am, Cm, Sc, Bk, Pu, Eu, Be, Th, Np, Hf, Al, U, Ti, Zr, Mn, V, Nb, Cr, Zn, Ga, Fe, Cd, In, Tl, Co, Ni, Mo, Sn and Pb. When these metals are adopted as the first metal, the standard oxidation reduction potential of the first metal is less than that of hydrogen in the raw material solution 23 in which the first metal is dissolved (see FIGS. 11 and 12). As a result, in the raw material solution 23 in which the first metal is dissolved, precipitation of the first metal as a hydroxide can be further suppressed.

In addition, in the production method of this embodiment, the second metal is also dissolved in the raw material solution 23 in which the first metal is dissolved. In other words, the pH of the raw material solution 23 in which the second metal is dissolved is also adjusted to be less than 7. According to this configuration, not only the first metal but also the second metal can be prevented from being precipitated as hydroxides. Therefore, the concentration of the second metal dissolved in the raw material solution 23 can be correctly adjusted and maintained at the intended concentration, and the oxide film 6 can be produced with high quality.

The second metal is not limited to gallium exemplified above. The second metal is selected from the group of consisting of Li, K, Rb, Cs, Ba, Ra, Sr, Ca, Na, Mg, No, Md, La, Fm, Y, Ce, Nd, Lu, Sm, Gd, Yb, Es, Ac, Cf, Am, Cm, Sc, Bk, Pu, Eu, Be, Th, Np, Hf, Al, U, Ti, Zr, Mn, V, Nb, Cr, Zn, Ga, Fe, Cd, In, Tl, Co, Ni, Mo, Sn and Pb. When these metals are adopted as the second metal, the standard oxidation reduction potential of the second metal is less than that of hydrogen in the raw material solution 23 in which the second metal is dissolved (see FIGS. 11 and 12). As a result, in the raw material solution 23 in which the second metal is dissolved, precipitation of the second metal as a hydroxide can be further suppressed. The second metal is different from the first metal.

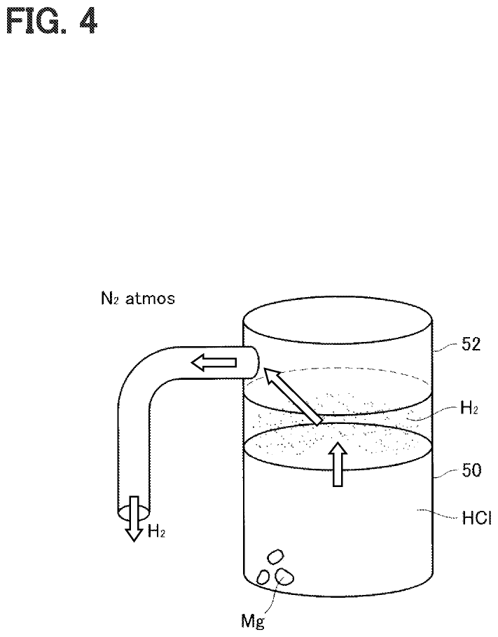

Next, the step of preparing the raw material solution 23 (S12 and S14 in FIG. 3) will be described with reference to FIG. 4. As shown in FIG. 4, in this step, a container 50 that is made of PTFE (polytetrafluoroethylene) is used. The container 50 can be sealed with a lid 52 that is also made of PTFE. PTFE is an example of a material free from silicon (Si). An exhaust passage is defined in the lid 52 or an upper portion of the container 50. The cross-sectional area of the exhaust passage is relatively small, and the gas generated in the container 50 is configured to be discharged little by little. Here, the first metal as a dopant is magnesium and the second metal that is a main element of the oxide film 6 is gallium.

First, in the container 50 with the lid 52, 0.05 mol of magnesium metal is dissolved in an acidic aqueous solution containing 0.11 mol of hydrogen chloride (HCl) (S12 in FIG. 3). In this procedure, the reaction of Mg+2HCl→MgCl₂+H₂ occurs to generate 0.05 mol of magnesium chloride (MgCl₂) and 0.05 mol of hydrogen gas (H₂). The generated hydrogen gas is gradually discharged through the exhaust passage, and the container 50 is maintained at a positive pressure relative to the atmosphere. The series of procedures are preferably performed in an atmosphere of nitrogen gas. Magnesium chloride immediately dissolves in water. The remaining 0.01 mol of HCl is almost completely ionized. Then, pure water is added into the aqueous solution to make a total volume of 1 L, and the pH is adjusted to a value that is less than 7 (S14 in FIG. 3). According to the above procedure, an aqueous solution having a pH of 2 and a magnesium concentration of 0.05 mol/L can be obtained. By adding this to the raw material solution 23 in which gallium, which is the second metal, is dissolved, the raw material solution 23 in which magnesium and gallium are dissolved and that has a pH less than 7 can be prepared.

In contrast, in the conventional method, the raw material solution is prepared by dissolving 0.05 mol of magnesium chloride in pure water to make the total volume of 1 L. As the solute at this time, magnesium chloride hexahydrate (MgCl₂.6H₂O) is often used. Magnesium chloride hexahydrate is obtained by dissolving magnesium hydroxide in hydrochloric acid to be neutralized and by concentrating it. However, in the heat treatment during the concentration, unintended impurities eluted from the container often contaminate. In particular, when a general borosilicate glass container is used, a small amount of silicon (Si) is eluted from the container. In this case, Si may be incorporated into a gallium oxide film in forming the film, and function as a donor. Thus, it significantly affects the electrical characteristics of the oxide film.

Further, it is difficult to obtain only hexahydrate by the concentration. That is, anhydride (MgCl₂), magnesium hydroxide (Mg(OH)₂), and magnesium chloride (MgCl(OH)) may be mixed through the concentration. In addition, hexahydrate (MgCl₂.6H₂O) is deliquescent and therefore easily absorbs water in the atmosphere. When magnesium hydroxide is contained in the presence of humidity, carbon dioxide may be incorporated through the reaction of 2Mg(OH)₂+CO₂→MgCO₃.Mg(OH)₂+H₂O. As a result, the oxide film 6 may contain carbon (C) as an unintended impurity. Magnesium hydroxide is less soluble in water than magnesium chloride and forms colorless colloidal particles in the aqueous solution. Thus, contamination of these impurities causes not only a quantification error, but also a difficulty in forming uniformly doped film.

Regarding these points, the container 50 made of a material free from silicon (Si) is used in the procedure of this embodiment. Thus, it is possible to prevent silicon from being mixed in the raw material solution 23. Further, by maintaining the container 50 at a positive pressure relative to the atmosphere, it is possible to prevent impurities in the atmosphere such as carbon from being mixed into the raw material solution 23. Therefore, not only the concentration of the first metal in the raw material solution 23 is stabilized, but also unintended contamination of impurities can be avoided. As a result, variations in characteristics due to the production method can be suppressed and the oxide film 6 can be formed with high quality.

### Second Embodiment

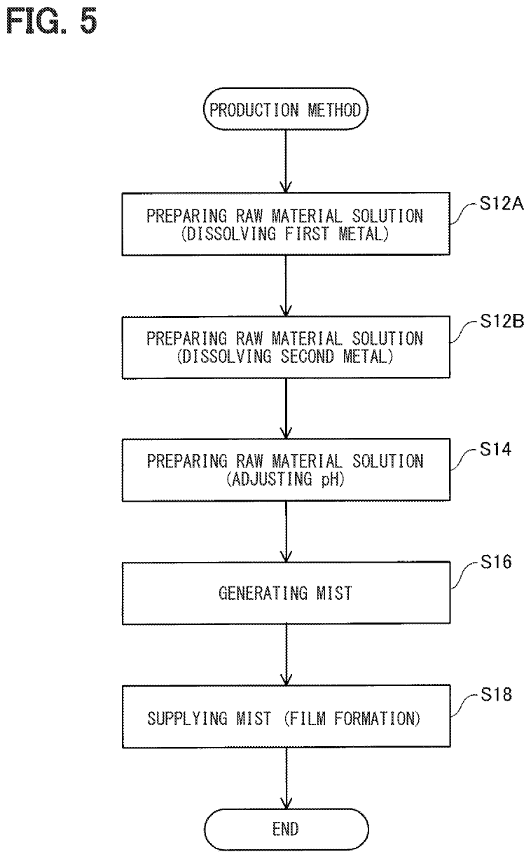

A production method of the second embodiment will be described with reference to FIGS. 5 to 7. As shown in FIG. 5, in the production method of this example, the step for preparing the raw material solution 23 (S12A, S12B, S14) are changed as compared with the production method of the first embodiment. Therefore, in the following description, the step for preparing the raw material solution 23 (S12A, S12B, S14) in this embodiment will be mainly described, and the description of other common portions will be omitted by adding the same reference numerals.

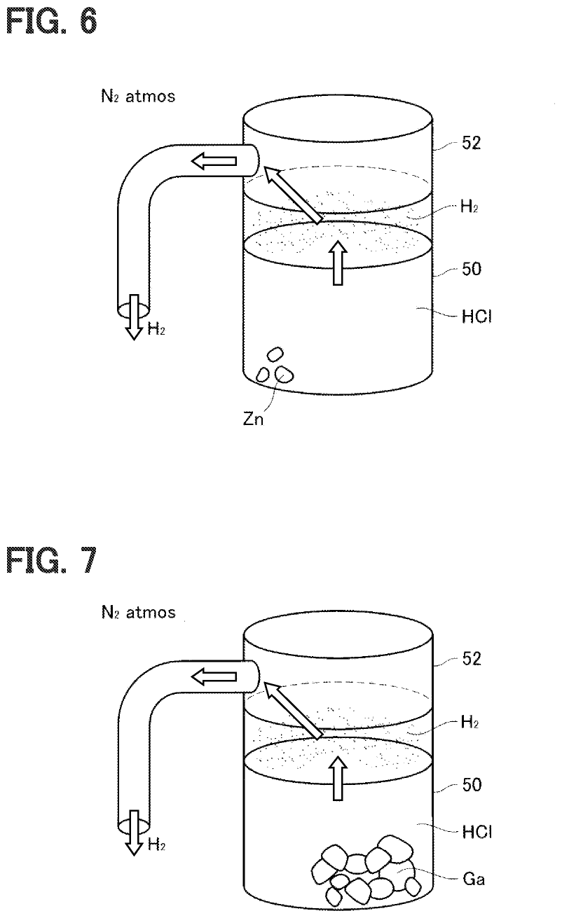

Also in this embodiment, the container 50 shown in FIG. 3 can be used in the step of preparing the raw material solution 23 (S12A, S12B, S14). Here, zinc (Zn) is used as the first metal serving as a dopant, and gallium is used as the second metal that is a main element of the oxide film 6. First, as shown in FIG. 6, 0.02 mol of zinc metal is dissolved in an aqueous solution containing 0.045 mol of hydrogen chloride (S12A in FIG. 5). At this time, a reaction of Zn+2HCl→ZnCl₂+H₂ occurs to generate 0.02 mol of hydrogen gas and an aqueous solution containing 0.02 mol of ZnCl₂ and 0.005 mol of hydrogen chloride. Next, as shown in FIG. 7, using similar container 50, 0.2 mol of gallium metal is dissolved in an aqueous solution containing 0.605 mol of hydrogen chloride (S12B in FIG. 5). At this time, a reaction of 2Ga+6HCl→2GaCl₃+3H₂ occurs to generate 0.3 mol of hydrogen gas and an aqueous solution containing 0.2 mol of gallium chloride (GaCl₃) and 0.005 mol of hydrogen chloride. After that, the aqueous solution produced in step S12A and the aqueous solution produced in step S12B are mixed with each other, and pure water is further added to make the total volume of 1 L, and the pH of the prepared solution is adjusted to be less than 7 (S14 in FIG. 5). As a result, the raw material solution 23 having a pH of 2, a zinc concentration of 0.02 mol/L, and a gallium concentration of 0.2 mol/L can be obtained. By using this raw material solution 23, the oxide film 6 made of zinc-doped gallium oxide can be formed.

### Third Embodiment

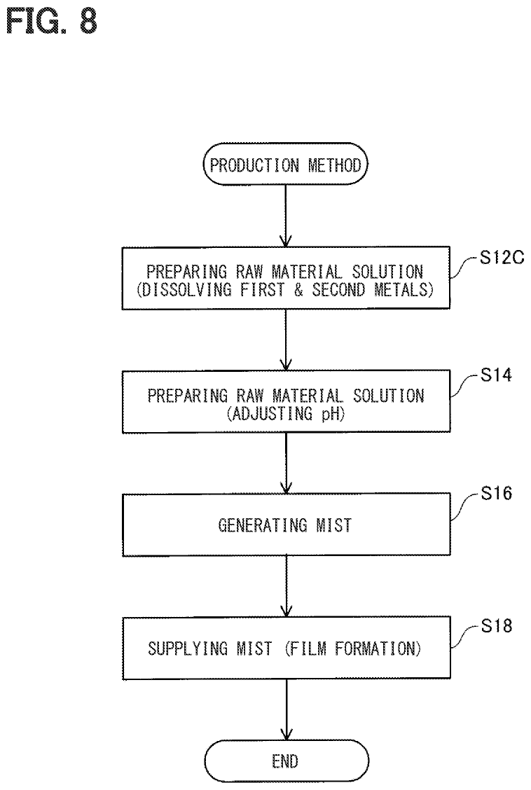

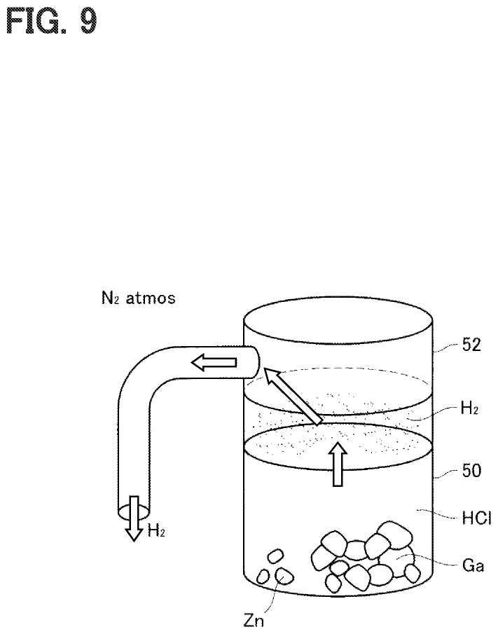

A production method of the third embodiment will be described with reference to FIGS. 8 and 9. As shown in FIG. 8, in the production method of this example, the step (S12C, S14) for preparing the raw material solution 23 are changed as compared with the production methods of the first embodiment and the second embodiment. Therefore, in the following description, the step for preparing the raw material solution 23 (S12C, S14) in this embodiment will be mainly described, and the description of other common portions will be omitted by adding the same reference numerals.

Also in this embodiment, the container 50 shown in FIG. 3 can be used in the step of preparing the raw material solution 23 (S12C, S14). Here, zinc is used as the first metal serving as a dopant, and gallium is used as the second metal that is a main element of the oxide film 6. First, as shown in FIG. 9, 0.02 mol of zinc metal and 0.2 mol of gallium metal are dissolved together in an aqueous solution containing 0.65 mol of hydrogen chloride in the container 50. At this time, it is preferable that the zinc metal and the gallium metal have granular shape and the container 50 be cooled from the outside. Thus, the zinc metal and the gallium metal can be slowly and gradually dissolved, so that the heat generation can be suppressed. Further, the series of operations may be carried out in an atmosphere of high-purity nitrogen gas.

Next, pure water is added into the aqueous solution prepared in step S120 to make the total volume of 1 L, and the pH is adjusted to be less than 7 (S14 in FIG. 8). As a result, the raw material solution 23 having a pH of 2, a zinc concentration of 0.02 mol/L, and a gallium concentration of 0.2 mol/L can be obtained. By using this raw material solution 23, the oxide film 6 made of zinc-doped gallium oxide can be formed.

### Fourth Embodiment

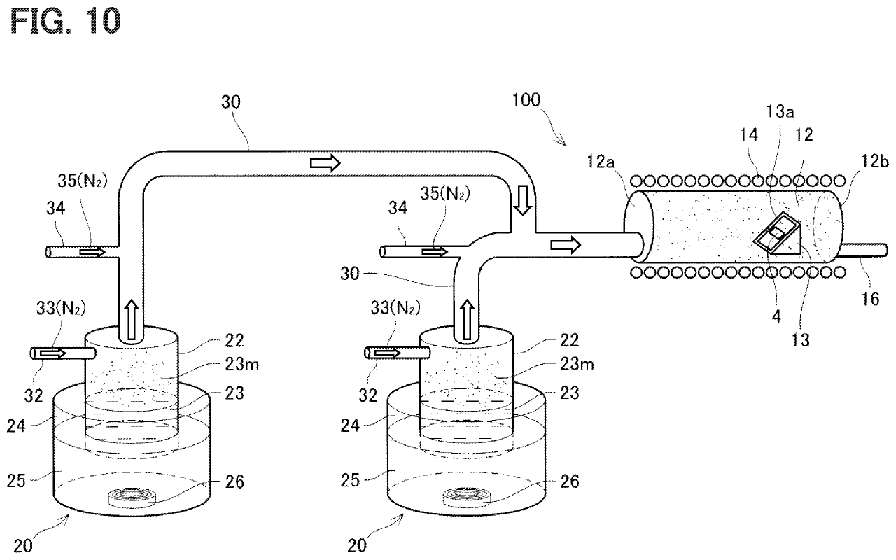

A production method of the fourth embodiment will be described with reference to FIG. 10. The production method of this embodiment is different from the production method of the first embodiment in that the method is carried out by a film forming apparatus 100 shown in FIG. 10. As shown in FIG. 10, the film forming apparatus 100 in this embodiment has two mist generating devices 20. That is, two kinds of raw material solutions 23 can be used in the film forming apparatus 100. Therefore, although not particularly limited, the first raw material solution 23 in which the first metal is dissolved is set in one of the mist generating devices 20, and the second raw material solution in which the second metal is dissolved is set in the other of the mist generating devices 20. In this case, the first and second raw material solutions 23 may have the same pH or may have different pH from each other.

Although specific examples of the techniques disclosed in the present disclosure have been described in detail above, these are merely examples and do not limit the scope of claims. The techniques described in the claims include various modifications of the specific examples illustrated above. The technical elements described in the present specification or the drawings exhibit technical usefulness alone or in various combinations, and are not limited to the combinations described in the claims at the time of filing. The techniques illustrated in the present specification or the drawings can achieve multiple objectives at the same time, and have a technical usefulness by achieving one of the objectives.

What is claimed is:

1. A method for producing a product including an oxide film of a second metal that is doped with a first metal, the method comprising:
generating a mist from a raw material solution in which both the first metal and the second metal are dissolved; and
supplying the mist to a surface of a substrate to form the oxide film on the surface of the substrate, wherein
a pH of the raw material solution is less than 7.

2. The method according to claim 1, wherein
in the raw material solution, a standard oxidation reduction potential of the first metal is less than that of hydrogen.

3. The method according to claim 1, wherein
the first metal is selected from the group consisting of Li, K, Rb, Cs, Ba, Ra, Sr, Ca, Na, Mg, No, Md, La, Fm, Y, Ce, Nd, Lu, Sm, Gd, Yb, Es, Ac, Cf, Am, Cm, Sc, Bk, Pu, Eu, Be, Th, Np, Hf, Al, U, Ti, Zr, Mn, V, Nb, Cr, Zn, Ga, Fe, Cd, In, Tl, Co, Ni, Mo, Sn, and Pb.

4. The method according to claim 1, wherein
a concentration of the first metal in the raw material solution is less than 1 mol/L.

5. The method according to claim 1, further comprising
dissolving the first metal in an acidic solution; and
adjusting a pH of the acidic solution to be less than 7.

6. The method according to claim 5, further comprising
dissolving the first metal in the acidic solution in a container made of a material free from Si.

7. The method according to claim 6, further comprising
maintaining the container at a positive pressure relative to the atmosphere with a gas generated when the first metal is being dissolved in the acidic solution.

8. The method according to claim 1, wherein
the second metal is selected from the group consisting of Li, K, Rb, Cs, Ba, Ra, Sr, Ca, Na, Mg, No, Md, La, Fm, Y, Ce, Nd, Lu, Sm, Gd, Yb, Es, Ac, Cf, Am, Cm, Sc, Bk, Pu, Eu, Be, Th, Np, Hf, Al, U, Ti, Zr, Mn, V, Nb, Cr, Zn, Ga, Fe, Cd, In, Tl, Co, Ni, Mo, Sn, and Pb.

9. The method according to claim 1, wherein
a concentration of the second metal in the raw material solution is less than 1 mol/L.

10. The method according to claim 1, further comprising:
dissolving the second metal in an acidic solution; and
adjusting a pH of the acidic solution to be less than 7.

11. The method according to claim 10, further comprising
dissolving the second metal in the acidic solution in a container made of a material free from Si.

12. The method according to claim 11, further comprising
maintaining the container at a positive pressure relative to the atmosphere with a gas generated when the second metal is being dissolved in the acidic solution.

13. The method according to claim 1, wherein
the oxide film is a single crystal film.

14. The method according to claim 1, wherein
the oxide film is a semiconductor film.

15. A method for producing a product including an oxide film of a second metal that is doped with a first metal, the method comprising:
generating a first mist from a first raw material solution in which the first metal is dissolved;
generating a second mist from a second raw material solution in which the second metal is dissolved; and
supplying the first mist and the second mist to a surface of a substrate to form the oxide film on the surface of the substrate, wherein
a pH of the first raw material solution is less than 7.

16. The method according to claim 15, wherein
a pH of the second raw material solution is less than 7.

17. The method according to claim 15, wherein
in the first raw material solution, a standard oxidation reduction potential of the first metal is less than that of hydrogen.

18. The method according to claim 15, wherein
in the second raw material solution, a standard oxidation reduction potential of the second metal is less than that of hydrogen.
